(19) United States
(12) Patent Application Publication
(10) Pub. No.: US 2008/0035980 A1
(43) Pub. Date: Feb. 14, 2008

(54) MASK FOR FORMING CONTACT HOLE

(76) Inventor: Young-Doo Jeon, Seoul (KR)

Correspondence Address: SHERR & NOURSE, PLLC, 620 HERNDON PARKWAY, SUITE 200, HERNDON, VA, 20170, US

(21) Appl. No.: 11/837,455

(22) Filed: Aug. 10, 2007

(30) Foreign Application Priority Data
Aug. 11, 2006 (KR) 10-2006-0076192

(51) Int. Cl. G03C 5/00; G03F 1/00; H01L 29/788

(52) U.S. Cl. 257/314; 430/319; 430/5; 257/E29.3

(57) ABSTRACT

Embodiments relate to a mask in which a mask pattern used for forming a contact hole may be designed such that any one of a horizontal-axis length and a vertical-axis length may be greater than the other in a photolithography process for forming the contact hole. In embodiments, a method for fabricating a mask having a plurality of patterns for forming a contact hole may be provided, in which the pattern may be designed differently depending on a distance between contact holes to be formed.

The present application claims priority under 35 U.S.C. 119 and 35 U.S.C. 365 to Korean Patent Application No. 10-2006-0076192 (filed on Aug. 11, 2006), which is hereby incorporated by reference in its entirety.

### BACKGROUND

As demand for electronic products such as mobile phones, digital cameras, MP3 players, and so forth, has increased, the demand for flash memory has also increased. The increase in demand may be as high as an average of more than 19 percent per year. Flash memory may represent a large portion of the semiconductor industry, and may have a market scale in an amount of $21.7 billion in 2007.

Flash memories may be classified into a NOR type and a NAND type according to a connection between cells each storing data. A parallel connection of cells may be a NOR type, and a series connection of cells may be a NAND type.

In manufacturing a flash memory device, contact holes may be formed in various sizes. Referring to FIGS. 1 through 4, contact holes may be classified according to a size of each contact hole.

Distortion of a contact hole may occur when there is another contact hole within a predetermined distance. This phenomenon will be described with reference to FIGS. 1 through 8.

FIGS. 1 through 4 illustrate SEM photographs of contact holes having a variety of sizes. A contact hole (a Cell Dense Hole: CDH) of FIG. 1 may have a size (a diameter) of 168 nm, a contact hole (a Cell Isolated Hole: CIH) of FIG. 2 may have a size of 166 nm, a contact hole (an Isolated Hole: IH) of FIG. 3 may have a size of 166 nm, and a contact hole (a Dense Hole: DH) of FIG. 4 may have a size of 171 nm.

Distinction between CIH and IH may be meaningless, but in the case of CIH, there may be another contact hole within a distance closer than in the case of IH.

A phenomenon of distortion of a contact hole will be further described with reference to CDH and DH shown in FIGS. 1 and 4.

In manufacturing a flash memory device, the same mask may be used even when contact holes having diverse sizes are formed. FIG. 6 illustrates a related art mask for forming a contact hole.

Referring to FIG. 6, in the related art mask, a rectangular mask design may be formed in a region corresponding to a position where a contact hole may be formed. A rectangular mask may be used to form the contact hole at a predetermined portion of a wafer.

CDH and DH illustrated in FIGS. 1 to 4 may all be formed using the mask shown in FIG. 6. In particular, referring to FIGS. 7 and 8, CDH may have a problem that it does not have a uniform circular profile because of a phenomenon of diffraction caused by the proximity of pattern.

CDH and DH may be distinguished according to whether there are other contact holes within a predetermined distance from a specific contact hole in an up/down direction and in a left/right direction.

In the case of DH, diffraction of light may occur because a rectangular mask may be used. However, diffraction may occur in all directions because contact holes may be formed in an up/down direction as well as a left/right direction.

However, although a diffraction phenomenon may occur in DH, a contact hole may increase in total size rather than being distorted in any one direction because there the diffraction phenomenon may occur with left/right and up/down symmetry.

To prevent a contact hole from inappropriately connecting with a neighbor contact hole because of distortion of the contact hole, it may be beneficial to improve contact holes arranged at a predetermined distance in a left/right direction such as CDH.

In CDH illustrated in FIG. 1, contact holes may be adjacently arranged at a predetermined distance in a left/right direction. However, even when contact holes are adjacently arranged at a predetermined distance only in an up/down direction, distortion can be predicted.

In other words, the contact hole distortion phenomenon can be described with a circularity ratio of a contact hole. Referring to FIG. 5, a circularity ratio of a contact hole may be equal to 0.936 (=0.1388/0.1482) when an X-direction length of a predetermined contact hole is equal to 0.1482 μm and a Y-direction length may be equal to 0.1388 μm.

Hence, when the circularity ratio is equal to 1, a contact hole may have a regular circle shape. A contact hole may have an oval shape, and may spread out more in a left/right direction as the circularity ratio decreases smaller than 1. A contact hole may have an oval shape, and may spread out more in an up/down direction as the circularity ratio increases greater than 1.

In this respect, a circularity ratio of CDH is less than 1. A method for preventing the occurrence of the distortion phenomenon may be beneficial.

### SUMMARY

Embodiments relate to a flash memory device, and more particularly, to a mask for forming a contact hole without distortion in a flash memory device and a method for manufacturing a flash memory device using the mask.

Embodiments relate to a mask that may prevent distortion of a contact hole and a method for manufacturing a flash memory device using the mask.

In embodiments, there may be provided a mask in which a mask pattern used for forming a contact hole may be designed such that any one of a horizontal-axis (X) length and a vertical-axis (Y) length is greater than the other in a photolithography process for forming the contact hole.

In embodiments, there may be provided a method for fabricating a mask having a plurality of patterns for forming a contact hole. The pattern may be designed differently depending on a distance between contact holes to be formed.

In embodiments, there may be provided a method for manufacturing a flash memory device. A rectangular mask may be used when contact holes may be adjacently arranged at a predetermined distance or less in a photolithography process for forming the contact hole.

### DRAWINGS

FIGS. 1 through 4 are SEM photographs of contact holes having various sizes.

FIG. 5 is a SEM photograph illustrating a circularity ratio of a contact hole.

FIG. 6 is a design of a related art mask for forming a contact hole.

FIGS. 7 and 8 illustrate a phenomenon of distortion of a contact hole in accordance with the related art.

FIG. 9 illustrates a design of a mask in according to embodiments.

FIG. 10 is a photograph of a contact hole formed using the mask, according to embodiments.

FIG. 11 is a graph simulating a profile of the contact hole, according to embodiments.

FIGS. 12 through 16 are graphs of profile of contact hole versus dose and sigma in a photolithography process for forming a contact hole, according to embodiments.

FIGS. 17 through 22 illustrate experimental data for determining a size of a mask and SEM photographs of contact holes according to embodiments.

FIGS. 23 and 24 are graphs of a comparison of contact-hole characteristics in accordance with the related art and embodiments.

FIG. 25 is a graph of variation of Depth Of Focus (DOF) characteristic versus dose in a photolithography process, according to embodiments.

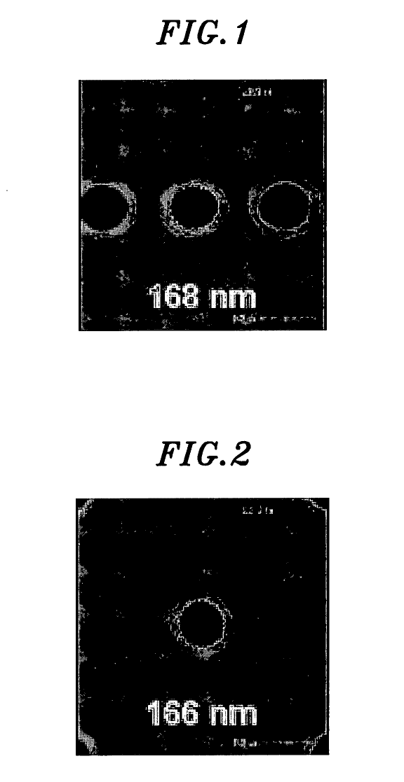

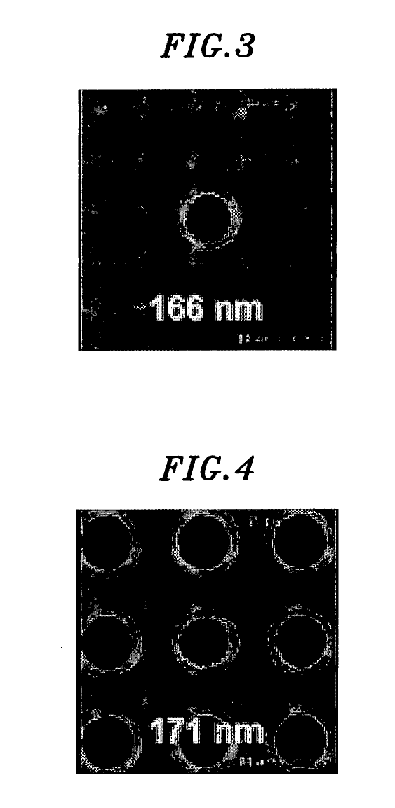

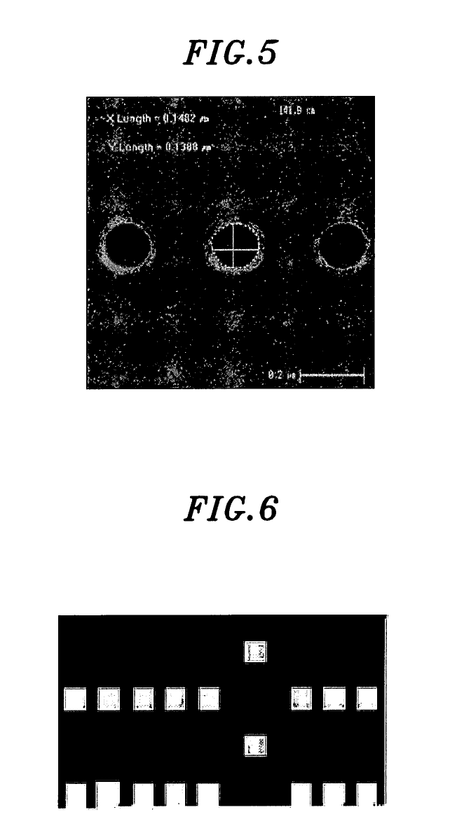

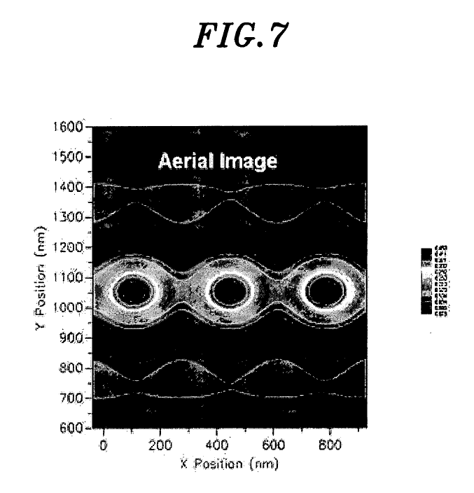

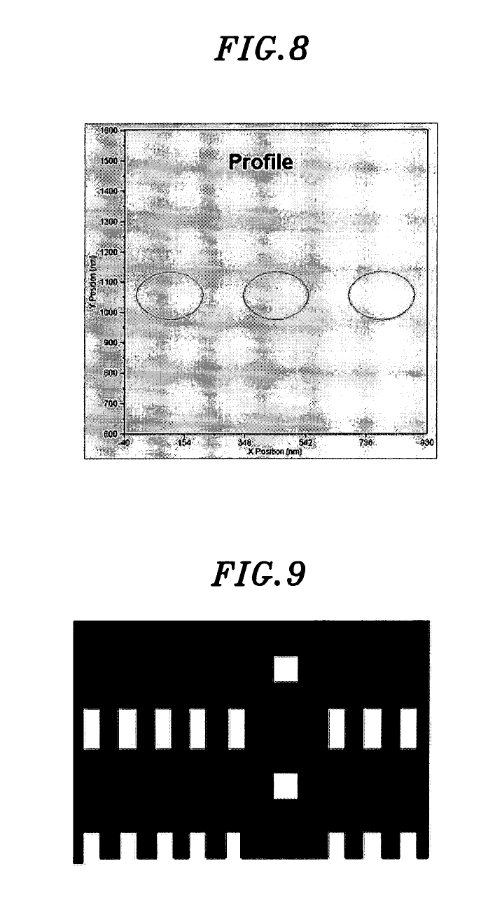

### DETAILED DESCRIPTION

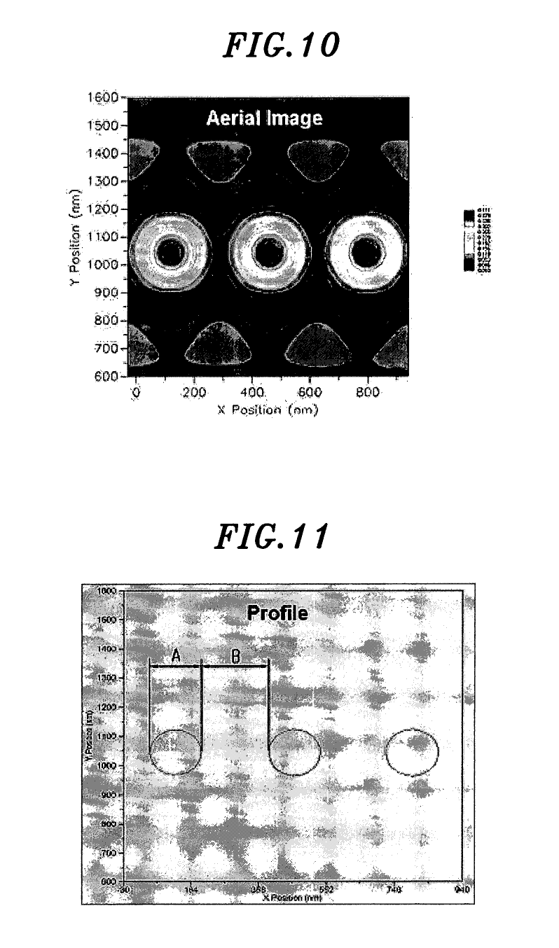

FIG. 9 illustrates a design of a mask according to embodiments. FIG. 10 is a photograph of a contact hole formed using the mask according to embodiments. FIG. 11 is a graph simulating a profile of the contact hole according to embodiments.

Referring to FIG. 9, the mask may be used to arrange contact holes that may be formed at a predetermined distance in a left/right direction (or up/down direction).

In other words, when a size (that is, a diameter) of a contact hole to be formed is equal to “A”, the mask according to embodiments may be used, if a distance (B) between two neighbor contact holes is smaller than “2×A”.

According to embodiments, the mask pattern may be designed to have a rectangular shape whose vertical-axis length may be greater than a horizontal-axis length. The mask pattern may be designed to have a shape whose vertical-axis length may be greater than a horizontal-axis length. Contact holes may be adjacently arranged in the direction of a horizontal axis.

Alternatively, if contact holes are formed at a predetermined distance (B) in an up/down direction, a ratio of vertical-axis length to horizontal-axis length of a mask for forming the contact hole may be different.

Referring to FIGS. 10 and 11, according to embodiments if contact holes are formed in a left/right direction, they may have an excellent circularity ratio in profile, if they are formed using a rectangular mask pattern.

In manufacturing a flash memory device, it may be necessary to provide desirable sigma (i.e., coherence factor) and dose if a mask according to embodiments is used. This may be because even when it is intended to form contact holes having a variety of sizes, it may use light with the same dose with the same sigma in the same process.

Accordingly, when using the design of the mask pattern formed to have a horizontal-axis length and a vertical-axis length greater than the horizontal-axis length, there may be provided a process condition (a sigma and a dose) that can be applied to contact holes (CDH, CIH, IH, and DH). The contact holes (CDH, CIH, IH, and DH) can be distinguished according to a contact-hole size and existence or absence of a neighbor contact hole.

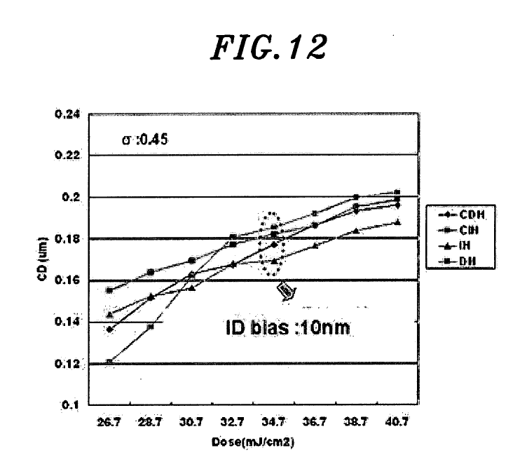

FIGS. 12 through 16 are graphs illustrating a profile of a contact hole versus dose and sigma in a photolithography process for forming a contact hole, according to embodiments.

The graphs of FIGS. 12 to 16 use a class of contact holes denoted by CDH, CIH, IH, and DH. CDH, CIH, IH, and DH can be distinguished according to a size of a target contact hole. For example, CDH may have a target Critical Dimension (CD) of 168 nm, CIH may have a target CD of 166 nm, IH may have a target CD of 166 nm, and DH may have a target CD of 171 nm. Specifically, CDH represents that contact holes may be arranged at a predetermined distance in a left/right direction.

FIGS. 12 to 15 show, by graph, experimental data on a CD (e.g., a diameter) of a contact hole that may be formed with a variable dose and with a fixed sigma of 0.45, 0.5, and 0.55 in a photolithography process, according to embodiments.

In additional detail, an ID bias (a bias between Isolated hole size and Dense hole size) may represent a size difference between the contact holes, for example, a size difference between CIH and CDH or a size difference between IH and DH. A size may become similar between the contact holes as the ID bias gets smaller.

A sigma and a dose may be factors for determining the ID bias in a photolithography process. Thus, a sigma and a dose resulting in a small ID bias may be identified through experiment.

In embodiments, a size difference between contact holes may be extremely small even when it may be intended to form the contact holes with various targets. A size difference between the contact holes may be large when distortion of the contact hole occurs. From this, a sigma and a dose resulting in a small ID bias can be selected.

The smallest ID bias in quantified data shown in FIG. 12 is equal to 10 nm. The smallest ID bias in quantified data shown in FIG. 14 is equal to 10 nm.

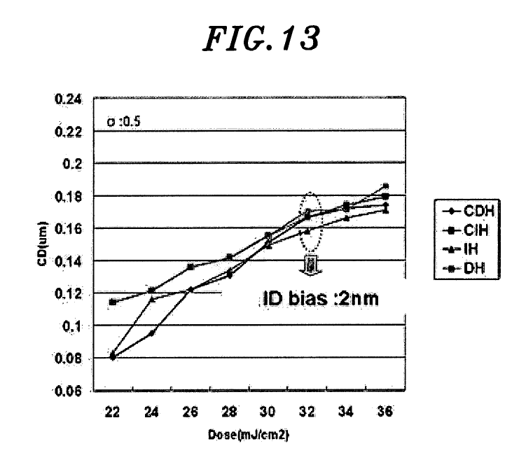

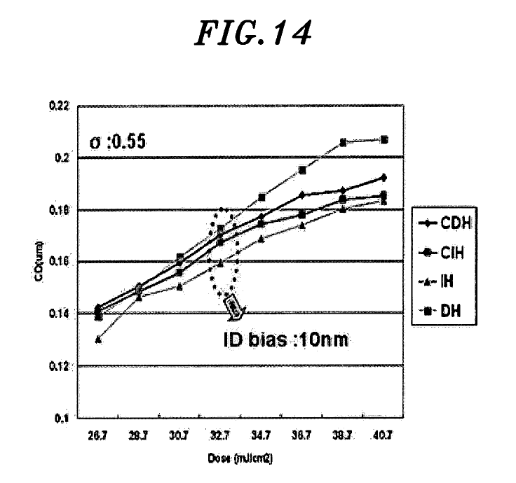

Alternatively, the smallest ID bias in quantified data shown in FIG. 13 may be equal to 2 nm. This is a result of a photolithography process implemented with a dose of about 32 mJ/cm² with a sigma of 0.5.

Accordingly, if a photolithography process is implemented with a sigma of 0.5, it may prevent a contact hole from being distorted.

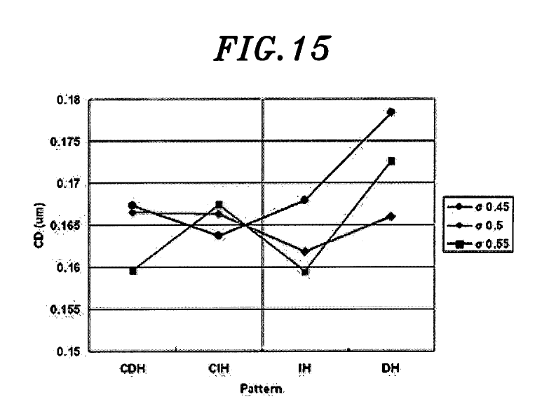

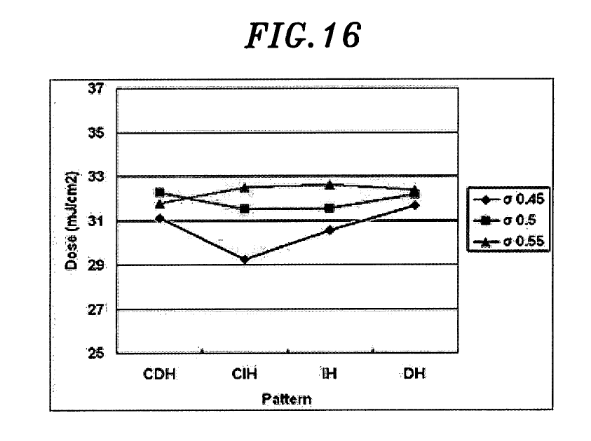

Referring to FIG. 15, if a photolithography process is implemented with a sigma of 0.5, contact holes may be properly formed according to a target CD while a size difference between the contact holes may not be as large.

FIG. 16 illustrates quantitative data for experimentally getting an amount of light (that is, a dose) that may be used in a photolithography process for forming a contact hole. It may be desirable that a dose be within a range of 31 mJ/cm² to 33 mJ/cm² when a sigma is equal to 0.5.

This may be because it is desirable that a size difference between contact holes is not great even where a photolithography process may be implemented with the same dose, in that even where contact holes may be formed to have diverse sizes with no great difference, it may be performed in the same photolithography process.

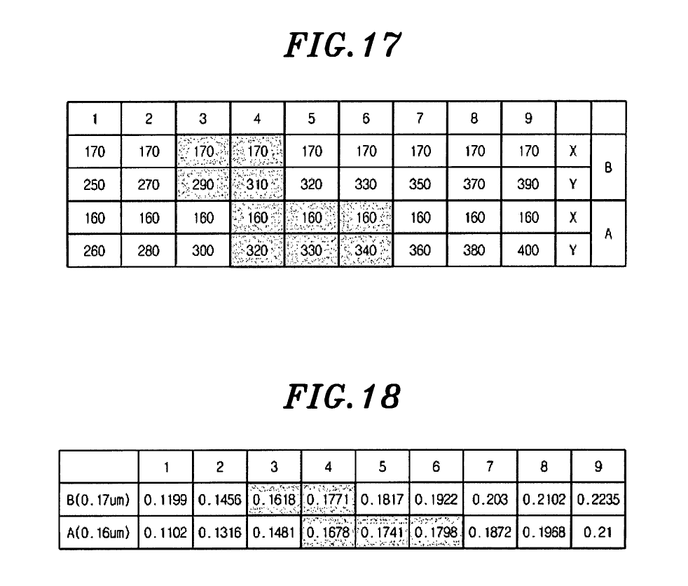

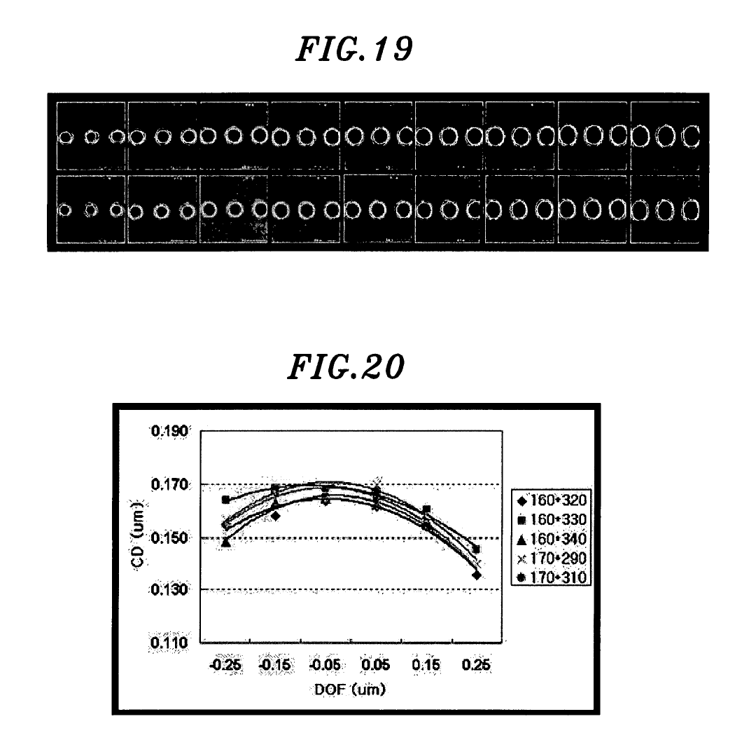

FIGS. 17 to 22 show experimental data for determining a size of a mask and SEM photographs of contact holes according to embodiments. FIG. 17 shows a mask design having diverse horizontal-axis (X) lengths and vertical-axis (Y) lengths, FIG. 18 shows a size of a contact hole formed with such a mask sample, and FIG. 19 shows a SEM photograph of the contact hole.

FIG. 18 shows data on sizes of contact holes formed using eighteen mask samples. From FIG. 18, a suitable mask sample (marked by bolded solid lines in FIGS. 17 to 19) may be selected at the time of forming CDH (a contact hole having a size of about 168 nm).

A contact hole having a size of about 0.1618 nm to 0.1771 nm can be selected from FIG. 18. In embodiments, a design of a mask pattern applied may be identified in FIG. 17.

In embodiments, samples with a horizontal-axis (X) length of 170 nm and a vertical-axis (Y) length of 290 nm to 310 nm and samples with a horizontal-axis (X) length of 160 nm and a vertical-axis (Y) length of 320 nm to 340 nm can be selected among a plurality of samples shown in FIG. 17.

Accordingly, a mask pattern for forming a contact hole may be designed such that a vertical-axis (Y) length may be within a range of about 290 nm to 310 nm when a horizontal-axis (X) length may be equal to 170 nm. The mask pattern may be designed such that a vertical-axis (Y) length may be within a range of about 320 nm to 340 nm when a horizontal-axis (X) length may be equal to 160 nm.

If a contact hole is formed using such a mask pattern, distortion of the contact hole may not occur, as in the SEM photograph shown within the bolded solid line of FIG. 19.

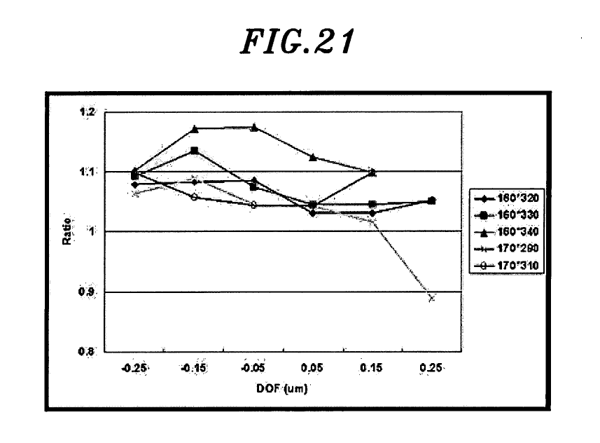

FIGS. 20 and 21 are graphs identifying a DOF characteristic and a circularity ratio characteristic when a contact hole is formed using a mask according to embodiments.

DOF characteristics and circularity ratios of a mask whose vertical-axis (Y) length may be within a range of about 290 nm to 310 nm when a horizontal-axis (X) length may be equal to 170 nm and a mask whose vertical-axis (Y) length may be within a range of about 320 nm to 340 nm when a horizontal-axis (X) length may be equal to 160 nm can be identified from quantified data shown in FIGS. 20 and 31.

In other words, the mask patterns may all have excellent DOF characteristics and have improved circularity ratios.

However, a 170*290 mask pattern may have an excessive variation of CD depending on DOF. A 160*340 mask pattern may have an oval shape being excessively long down to the extent that a circularity ratio comes close to 1.2. Thus, they may be inappropriate.

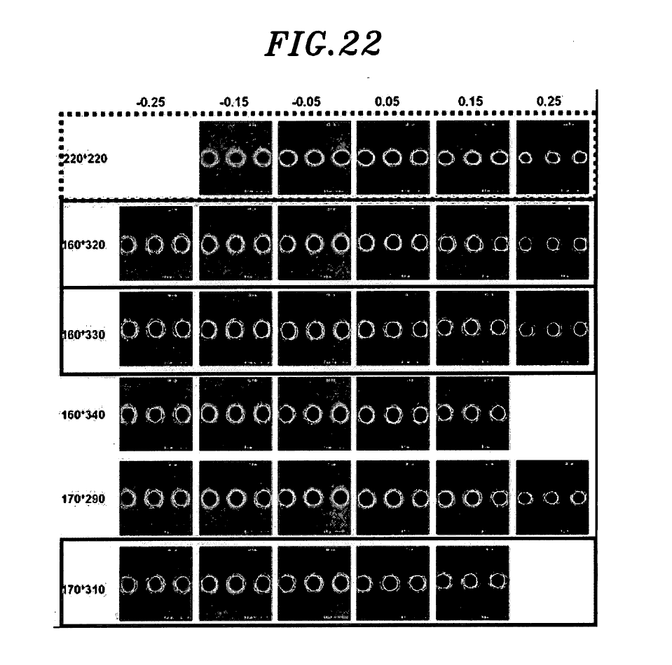

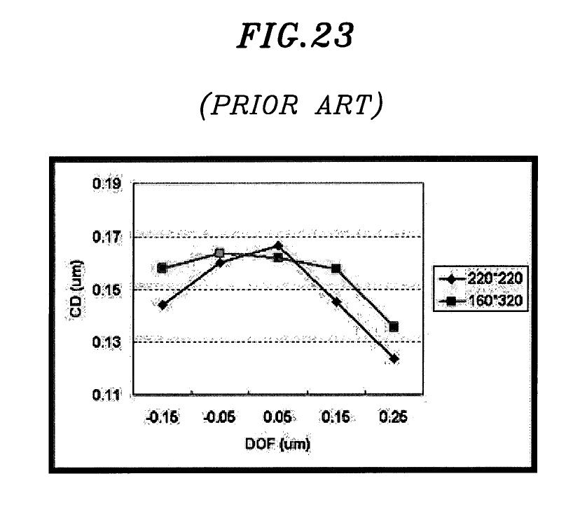

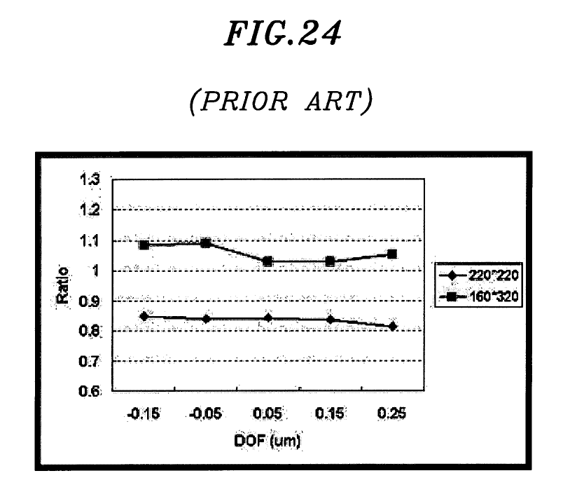

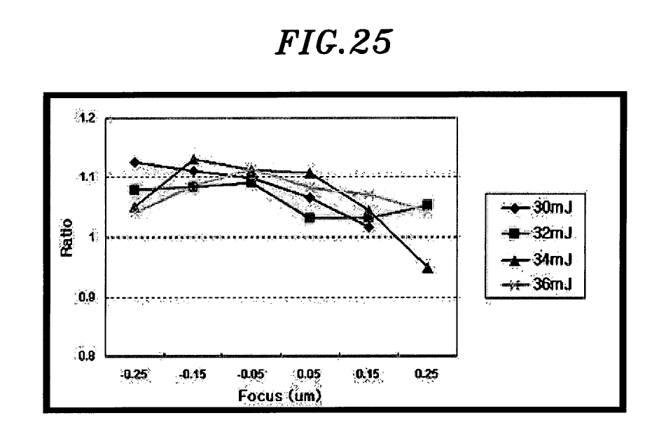

FIG. 22 is a SEM photograph of a contact hole according to a mask size, according to embodiments. FIGS. 23 and 24 are graphs for a comparison of contact-hole characteristics in accordance with the related art and embodiments. FIG. 25 is a graph of variation of DOF characteristic versus dose in a photolithography process.

FIG. 22 illustrates SEM photographs of contact holes formed using masks having sizes of 160*320, 160*330, and 170*310.

As shown, a phenomenon of distortion of a contact hole may be remarkably reduced.

The contact-hole characteristics in accordance with the related art and embodiments will be described with reference to FIGS. 23 and 24. In accordance with embodiments, a degree of variation of CD depending on a variation of DOF gets small and a circularity ratio also comes closer to “1”.

Referring to FIG. 24, a photolithography process may be implemented with greater easiness, as DOF gets large. Even if DOF is equal to the maximum of 0.25, a circularity ratio approximately comes close to 1 when the photolithography process may be implemented with a dose of 32 mJ/cm².

However, a dose of about 31 mJ/cm² to 33 mJ/cm² may be used in consideration that a dose of 30 mJ/cm² and a dose of 34 mJ/cm² may be used.

Embodiments may have an advantage of preventing a phenomenon of distortion of a contact hole, and may make it possible to manufacture a flash memory device having an excellent operation characteristic.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A mask, comprising:
a mask pattern configured to form a contact hole, wherein the mask pattern is designed such that any one of a horizontal-axis length and a vertical-axis length is greater than the other in a photolithography process to form the contact hole.

2. The mask of claim 1, wherein the mask pattern comprises a rectangular shape.

3. The mask of claim 2, wherein the mask pattern comprises a rectangular shape when a distance between contact holes is smaller than two times of a size of the contact hole.

4. The mask of claim 1, wherein a length of the horizontal-axis of the mask pattern is within a range of 160 nm to 170 nm, and a length of the vertical-axis is within a range of 290 nm to 310 nm and a range of 320 nm to 340 nm.

5. A method for fabricating a mask having a plurality of patterns for forming contact holes, comprising:
determining a distance between contact holes to be formed; and
selecting a design pattern according to a distance between contact holes to be formed.

6. The method of claim 5, wherein when the contact holes are adjacently formed in a predetermined direction, the mask pattern is designed to have a rectangular shape having a short length in the direction in which contact holes are arranged.

7. The method of claim 5, wherein the mask pattern is designed to have a rectangular shape when a distance between the contact holes is smaller than two times of a size of the contact hole.

8. The method of claim 5, wherein a length of the horizontal-axis of the mask pattern is within a range of 160 nm to 170 nm, and a length of the vertical-axis is within a range of 290 nm to 310 nm and a range of 320 nm to 340 nm.

9. The method of claim 5, comprising performing a photolithography process with a sigma of 0.5 and with a dose ranging from 31 mJ/cm² to 33 mJ/cm².

10. The method of claim 5, further comprising:
determining an arrangement of the contact holes; and
performing a photolithography process using a rectangular mask when contact holes are adjacently arranged at a predetermined distance or less to form the contact holes.

11. The method of claim 10, further comprising forming a flash memory device using the contact holes.

12. The method of claim 10, wherein the mask pattern is formed such that a horizontal-axis length is within a range of 160 nm to 170 nm, and wherein the mask pattern is formed such that a vertical-axis length is within a range of 290 nm to 310 nm and a range of 320 nm to 340 nm.

13. The method of claim 10, wherein the photolithography process is implemented with a sigma of 0.5 with a dose ranging from 31 mJ/cm² to 33 mJ/cm².

14. A flash memory device, comprising:
a plurality of contact holes formed using a photolithography process,
wherein, in the photolithography process, a rectangular mask is used if the plurality of contact holes are adjacently arranged at a predetermined distance or less.

15. The device of claim 14, wherein the predetermined distance is two times a size of the contact hole.

16. The device of claim 14, wherein the mask pattern is formed such that a horizontal-axis length is within a range of 160 nm to 170 nm, and a vertical-axis length is within a range of 290 nm to 310 nm and a range of 320 nm to 340 nm.

17. The device of claim 14, wherein the photolithography process is implemented with a sigma of 0.5 with a dose ranging from 31 mJ/cm² to 33 mJ/cm².
